(19) United States
(12) Patent Application Publication
(10) Pub. No.: US 2013/0001717 A1
(43) Pub. Date: Jan. 3, 2013

(54) PERPENDICULAR MRAM WITH MTJ INCLUDING LAMINATED MAGNETIC LAYERS

(76) Inventors: Yuchen Zhou, San Jose, CA (US); Yiming Huai, Pleasanton, CA (US); Rajiv Yadav Ranjan, San Jose, CA (US); Jing Zhang, Los Altos, CA (US); Roger Klas Malmhall, San Jose, CA (US)

(21) Appl. No.: 13/538,863

(22) Filed: Jun. 29, 2012

Related U.S. Application Data
(60) Provisional application No. 61/504,156, filed on Jul. 1, 2011.

(51) Int. Cl. H01L 29/82

(52) U.S. Cl. 257/421; 257/E29.323

(57) ABSTRACT

Thin film perpendicular magnetic multilayer structures which can be used in various thin film magnetic structures are described. One multilayer structure embodiment is formed by interlacing a soft magnetic layer and a FePt based magnetic layer in N repeats, where N is a positive integer. Various MRAM MTJ structures are described using multilayer structure embodiments for a free layer, a reference layer, and a pinned layer according to the invention.

### RELATED APPLICATION

This application is related to provision patent application filed on Jul. 1, 2011 bearing Ser. No. is 61/504,156 and the benefits of this provisional application are claimed under 35 U.S.C. 119(e).

### FIELD OF THE INVENTION

The present invention relates to the thin film structures in magnetoresistive random access memory (MRAM) cells including magnetic tunnel junctions (MTJ) memory elements and more particularly to thin film structures in the MTJ.

### BACKGROUND OF THE INVENTION

Magnetoresistive random access memory (MRAM) cells including magnetic tunnel junctions (MTJ) memory elements can use magnetic orientations that are in-plane or perpendicular. FIG. 1 illustrates one type of MRAM cell 10P which is designed for perpendicular magnetization of the MTJ layer structure 200P with respect to the film surface. At a minimum an MTJ includes a free magnetic layer and a pinned magnetic layer separated by a barrier layer. The barrier layer can also be called a spacer or junction layer. The MTJ 200P in this example includes a free magnetic layer 11, a nonmagnetic barrier or junction layer 12, a reference magnetic layer 13, an antiferromagnetic exchange coupling layer 14, and a pinned magnetic layer 15. An MRAM cell structure typically includes a top metal contact 21 and a bottom metal contact 22. The metal contacts are also referred to as electrodes. The reference magnetic layer 13 is antiferromagnetically exchange coupled to the pinned magnetic layer 15, which has a fixed magnetization direction. The free magnetic layer has a magnetization direction that is switchable in either of two directions. The order of the magnetic layers can also be reversed so that the free layer is the top most layer. A minimum

The resistivity of the whole MTJ layer stack changes when the magnetization of the free layer changes direction relative to that of the reference layer, exhibiting a low resistance state when the magnetization orientation of the two ferromagnetic layers is substantially parallel and a high resistance when they are anti-parallel. Therefore, the cells have two stable states that allow the cells to serve as non-volatile memory elements.

The MRAM cells in an array on a chip are connected by metal word and bit lines (not shown). Each memory cell is connected to a word line and a bit line. The word lines connect rows of cells, and bit lines connect columns of cells. Typically CMOS structures 24 include a selection transistor which is electrically connected to the MTJ stack through the top or bottom metal contacts. The direction of the current flow is between top or bottom metal contacts.

Reading the state of the cell is achieved by detecting whether the electrical resistance of the cell is in the high or low state. Writing the cells requires a sufficiently high DC current flowing in the direction through the MTJ stack between the top and bottom metal contacts to induce a spin transfer torque that orients (switches) the free layer into the desired direction. The amount of current needed to write the cells is at least slightly higher than the current that flows during the read process, so that a read operation does not change the state of the cell.

Laminated thin film magnetic structures include multiple layers or sublayers that work together to perform the function of a single homogeneous layer in the overall design of the device. For example, the free layer as described above can be composed of multiple layers or sublayers that in combination provide the function of the free layer in the design of the MTJ.

### SUMMARY OF THE INVENTION

Embodiments of the invention describe thin film perpendicular magnetic multilayer structures which can be used in various thin film magnetic structures. One multilayer structure embodiment is formed by interlacing a soft magnetic layer and a FePt based magnetic layer in N repeats, where N is a positive integer. Various MRAM MTJ structures are described using multilayer structure embodiments for a free layer, a reference layer, and a pinned layer according to the invention.

### BRIEF DESCRIPTION OF THE FIGURES

FIG. 1 is an illustration of an MRAM cell according to the prior art including MTJ memory element designed for perpendicular magnetization of the MTJ layer structure.

FIG. 2 illustrates a first perpendicular magnetic multilayer stack embodiment of the invention which can be used in various thin film magnetic structures.

FIG. 3 is a graph of the perpendicular magnetic moment versus an applied perpendicular magnetic field for a multilayer stack embodiment of the invention.

FIG. 4 illustrates a second perpendicular magnetic multilayer stack embodiment of the invention which can be used in various thin film magnetic structures.

FIG. 5 illustrates a third perpendicular magnetic multilayer stack embodiment of the invention used as a free layer above an underlayer in an MRAM MTJ structure.

FIG. 6 illustrates a fourth perpendicular magnetic multilayer stack embodiment of the invention used as a central reference layer in an MRAM MTJ structure.

FIG. 7 illustrates a fifth perpendicular magnetic multilayer stack embodiment of the invention used as a top pinned layer in an MRAM MTJ structure.

FIG. 8 illustrates a sixth perpendicular magnetic multilayer stack embodiment of the invention used as a central free layer in an MRAM MTJ structure.

FIG. 9 illustrates a seventh perpendicular magnetic multilayer stack embodiment of the invention used as a reference layer in an MRAM MTJ structure with a central free layer.

FIG. 10 illustrates an eight perpendicular magnetic multilayer stack embodiment of the invention used as a pinned layer in an MRAM MTJ structure with a central free layer.

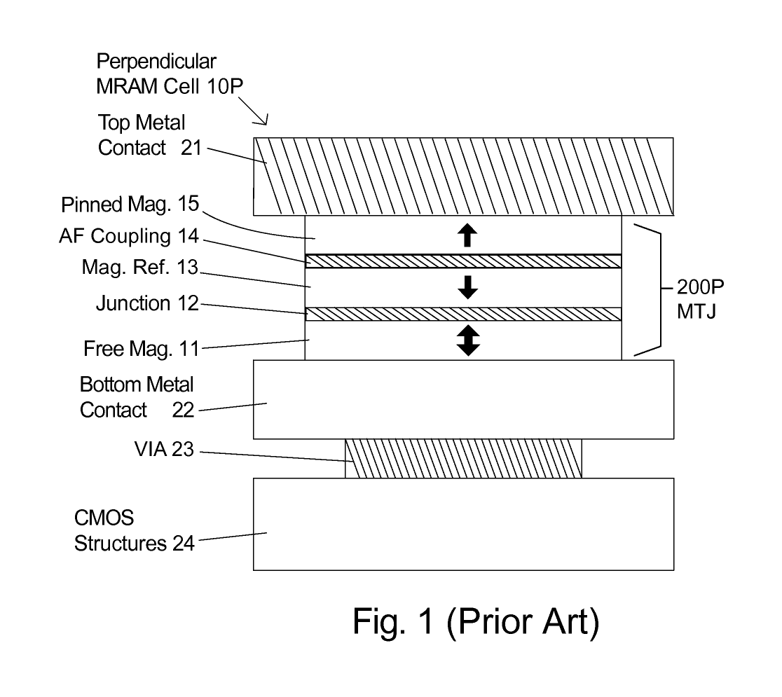

### DETAILED DESCRIPTION OF THE INVENTION

In the following description of the embodiments, reference is made to the accompanying drawings that form a part hereof, and in which is shown by way of illustration of the specific embodiments in which the invention may be practiced. It should be noted that the figures discussed herein are not drawn to scale and do not indicate actual or relative sizes.

### Embodiment 1

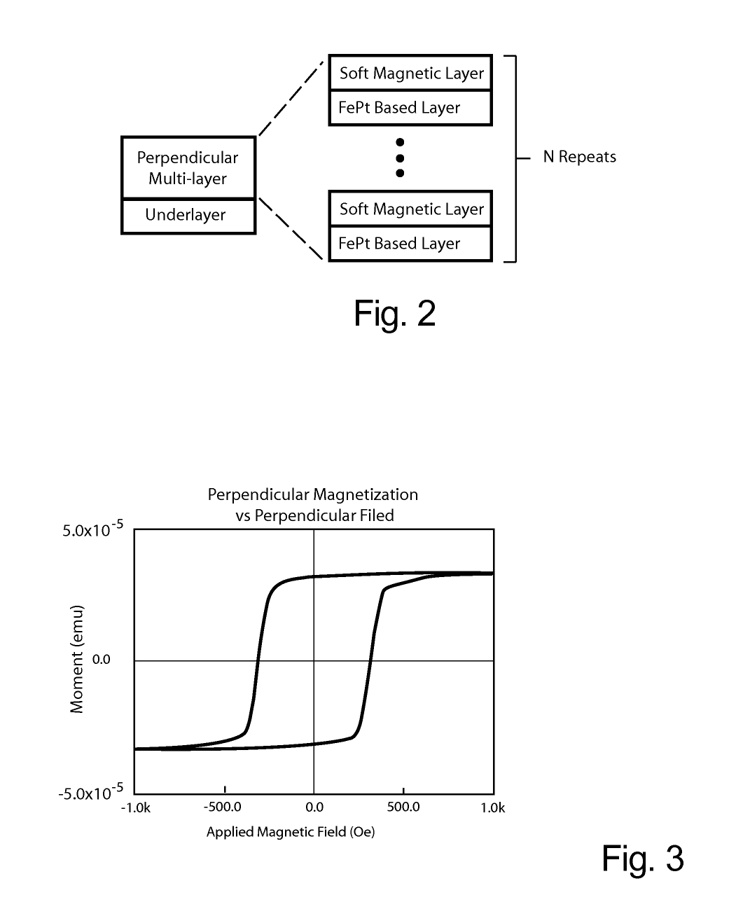

In the first embodiment that will be described the perpendicular multilayer structure, as illustrated in FIG. 2, with perpendicular magnetic anisotropy and a magnetization perpendicular to the film plane is formed by interlacing a soft magnetic layer and a FePt based magnetic layer in N repeats, where N is a positive integer. Two or more repeats is preferred for higher anisotropy from the additional interfaces between the soft magnetic and perpendicular magnetic layers, because such interfaces can induce perpendicular magnetic anisotropy in the soft magnetic layer.

The soft magnetic layer is an alloy composed of any suitable material including, but not limited to, the group consisting of Co, Fe, B, Ta, Ti, Cr, Ni, O, Mg, Cu, Hf, and Pt. For example, the soft magnetic layer can be composed of CoFeB, or CoFeBX, or CoFe, or a multilayer of CoFeBX and CoFe, or a multilayer of CoFeB and CoFe, where X can be any element from the group consisting of Ta, Ti, Cr, Ni, O, Mg, Cu, and Hf. The soft magnetic layer can also be composed of Co, Fe, B, and any element of the group consisting of Ta, Ti, Cr, Ni, O, Mg, Cu, and Hf The soft magnetic layer preferably has thickness between 0.2 nm to 2 nm.

The FePt based magnetic layer is an alloy composed of Fe and Pt and any of, but not limited to, the group consisting of Cu, B, Ta, Ti, V, Cr, Si, C, and Ru. For example, the FePt based layer can be composed of FePtCuB. The FePt based magnetic layer preferably has thickness between 0.2 nm to 2 nm.

The multilayered structure can end with a soft magnetic layer or a FePt based magnetic layer on either top or bottom of the stack.

The underlayer, as shown in FIG. 2, is used to promote crystalline growth of the multilayer stack for higher perpendicular anisotropy. The underlayer is an alloy layer or a single composition layer composed of any of, but not limited to, the group consisting of Cr, Mo, Ta, Ru, Co, Fe, B, Cu, Ti, V, and Pt. For example, the underlayer can be a multilayer structure composed, from bottom to top, of: a Ta layer, a CoFeB layer, a CrMo layer. The underlayer can also be a MgO layer, or a Ru layer, or a Ta layer, or a CrMo layer, or a Pt layer, or a ruthenium oxide layer. The underlayer can also generally be a material deposited to have an amorphous structure. The underlayer can also be a MgO layer, or a Ru layer, or a Ta layer, or a layer composed of at least Co, Fe, B and any other element of the group consisting of Ta, Ti, Cr, Ni, O, Mg, Cu, and Hf.

The perpendicular anisotropy can be achieved by depositing the multilayered structure when the underlayer and substrate is held at temperature between 200° C. to 500° C. The perpendicular anisotropy can also be achieved by annealing the deposited multilayer stack at temperature of 200° C. to 500° C. A perpendicular magnetic field may be applied during the annealing process.

The multilayered structure may be capped with a layer composed of any of, but not limited to the group consisting of Ta, Ti, Ru, Mg, O, Cu, V, Hf, Fe, and Pt.

The multilayered structure may be used as ferromagnetic layer in variety of magnetic thin film devices including magnetoresistive sensing devices; as a part of a data storage element, such as a MTJ in an MRAM cell; or as a part of a data storage unit, such as a recording bit in a magnetic recording medium.

The advantages of the multilayer FePt based multilayered structure according to the invention when compared with single layer FePt based field include:
Better squareness in the MH curve (see FIG. 3), which indicates uniform films with good coherent switching and smaller switching field distribution if patterned into small size (dimension <100 nm).
Easy forming of perpendicular anisotropy at low deposition temperature.
FePt/CoFeB multilayer stack makes it easy to adapt to magnetic tunnel junction (MTJ) without significant tunneling.

### Embodiment 2

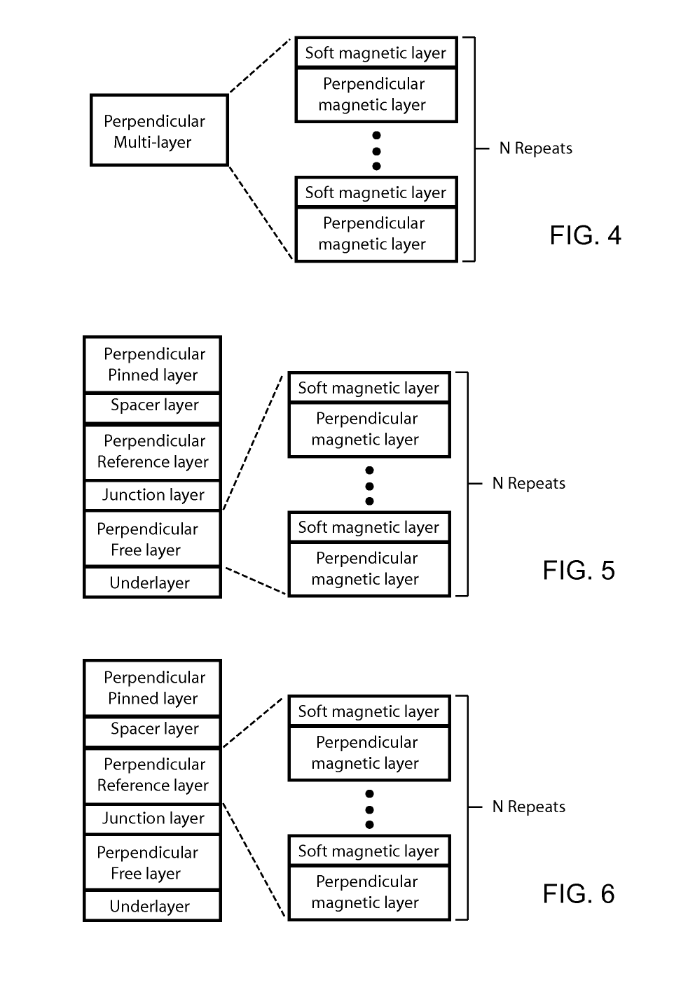

The perpendicular magnetic multilayer structure in this second embodiment as illustrated in FIG. 4 is formed by interlacing a soft magnetic layer and a perpendicular magnetic layer in N repeats, where N is a positive integer equal to or larger than 1. As noted above two or more repeats is preferred for higher anisotropy for this embodiment and the embodiments described below.

The soft magnetic layer has an amorphous structure when deposited. The soft magnetic layer is an alloy composed of any of, but not limited to, the group consisting of Co, Fe, B, Ta, Ti, Cr, Ni, O, Mg, Cu, Hf, Pt, and Zr. For example, the soft magnetic layer can be composed of CoFeB. The soft magnetic layer can also be composed of CoFeBX, or CoFeX, or FeX, or NiFeX, or CoX, or CoNiX, where X can be any elements Ta, Ti, Cr, Ni, O, Mg, Cu, Hf, or Sm. The soft magnetic layer can also be composed of at least one rare earth element of Tb, Gd, Nd, Sm, and at least one element of Co, Fe, Ni, B, or Mn. The soft magnetic layer can be composed of TbCoFe, or GdCoFe. The soft magnetic layer preferably has thickness between 0.2 nm to 2 nm.

The repeating perpendicular magnetic layer may be composed of:
FePtY, where Y can be any of, but not limited to , Cr, Cu, B, Ta, Ti, V, Si, C, Ru, O, Zr.
CoPtY, where Y can be any of, but not limited to , Cr, Cu, B, Ta, Ti, V, Si, C, Ru, O, Zr.
CoCrZ, where Z can be any of, but not limited to, Pt, Pd, Ta, Ti, Zr, Si, Al.
CoCrZ, where Z can be any of, but not limited to, Pt, Pd, Ta, Ti, Zr, Si, Al, in mixture within an oxide, where the oxide can be, silicon-oxide, MgO, alumina, zinc-oxide, or ruthenium oxide.
Co/Pd multilayer, or CoFe/Pd multilayer, or Co/Pt multilayer, or CoFe/Pt multilayer, or Fe/Pt multilayer, or Co/Ni multilayer, or CoFe/Ni multilayer.

The perpendicular magnetic layer preferably has thickness between 0.2 nm to 2 nm. The perpendicular magnetic layer can have an L10 lattice structure when exhibiting a perpendicular anisotropy. The multilayer structure can be ended with either the soft magnetic layer or the perpendicular magnetic layer on either top or bottom of the stack.

An underlayer beneath the stack may be used to promote perpendicular anisotropy of the stack. The underlayer is composed of any one or multiple elements of, but not limited to, Cr, Mo, Ta, Ru, Co, Fe, B, Cu, Ti, V, Pt. For example, the underlayer can be a MgO layer, or a Ru layer, or a Ta layer, or a TiCr layer, or a Pt layer, or a Pd layer. The underlayer can have an amorphous structure.

The fabrication method to achieve perpendicular anisotropy can include depositing the multilayer stack when substrate is held between 200° C. to 500° C. The perpendicular anisotropy can be achieved by annealing the deposited multilayer stack at temperature of 200° C. to 500° C. A perpendicular magnetic field may be applied during the annealing process.

The multilayer structure may be capped with layer composed of any of, but not limited to, Ta, Ti, Ru, Mg, O, Cu, V, Hf, Fe, Pt, or ruthenium oxide.

The perpendicular magnetic multilayer stack in this embodiment can be used as described above for the first embodiment.

### Embodiment 3—MRAM MTJ Stack with Free Layer having Multilayer Structure

In the third embodiment as illustrated in FIG. 5, the perpendicular free layer, perpendicular reference layer and perpendicular pinned layer all have a perpendicular magnetic anisotropy and a magnetization perpendicular to the film plane. The magnetizations of perpendicular reference layer and perpendicular pinned layer are opposite to each other. The junction layer can be, but is not limited to, MgO, alumina, Cu or Cu nano-pillars within an oxide.

When different electric current directions are applied through the stack, the perpendicular free layer magnetization may be switched into different orientation along the perpendicular direction due to the spin transfer torque from the perpendicular reference layer.

The spacer layer may be a non-magnetic layer of, but not limited to, Ru, Ta, Ti, MgO, Cu, Hf, ZnO, alumina, or ruthenium oxide. The spacer layer can be designed to produce an anti-ferromagnetic coupling between the perpendicular reference layer and perpendicular pinned layer, with a composition of Ru, Cu or MgO.

In this embodiment the perpendicular free layer is a multilayer stack formed according to the invention by interlacing soft magnetic layer and perpendicular magnetic layer in N repeats, where N is a positive integer equal to or larger than 1.

The soft magnetic layer has an amorphous layer when deposited. The soft magnetic layer is an alloy composed of any of, but not limited to, Co, Fe, B, Ta, Ti, Cr, Ni, O, Mg, Cu, Hf, Pt, or Zr. For example, the soft magnetic layer can be composed of CoFeB. The soft magnetic layer can also be composed of CoFeBX, or CoFeX, or FeX, or NiFeX, or CoX, or CoNiX, where X can be any element of, Ta, Ti, Cr, Ni, O, Mg, Cu, Hf, or Sm. The soft magnetic layer can also be composed of at least one rare earth element of Tb, Gd, Nd, Sm, and at least one element of Co, Fe, Ni, B, or Mn. The soft magnetic layer can also be composed of TbCoFe, or GdCoFe. The soft magnetic layer preferably has thickness between 0.2 nm to 2 nm. The repeating perpendicular magnetic layer may be composed of:
FePtY, where Y can be any of, but not limited to , Cr, Cu, B, Ta, Ti, V, Si, C, Ru, O, or Zr.
CoPtY, where Y can be any of, but not limited to , Cr, Cu, B, Ta, Ti, V, Si, C, Ru, O, or Zr.
CoCrZ, where Z can be any of, but not limited to, Pt, Pd, Ta, Ti, Zr, Si, or Al.
CoCrZ, where Z can be any of, but not limited to, Pt, Pd, Ta, Ti, Zr, Si, Al, in mixture within an oxide, where the oxide can be, silicon-oxide, MgO, alumina, zinc-oxide, or ruthenium oxide.
Co/Pd multilayer, or CoFe/Pd multilayer, or Co/Pt multilayer, or CoFe/Pt multilayer, or Fe/Pt multilayer, or Co/Ni multilayer, or CoFe/Ni multilayer.
   The perpendicular layer preferably has thickness between 0.2 nm to 2 nm.The multilayer stack can end with a soft magnetic layer or a perpendicular magnetic layer on either top or bottom of the stack.

The perpendicular free layer structure can have an interface layer abutting the junction layer, and can be composed of CoFe, or Fe, or CoFeB, where Fe atomic percentage is larger than or equal to 40%.

The underlayer beneath the stack can be used to promote perpendicular anisotropy of the stack. The underlayer can be composed of any one or multiple elements of, but not limited to, Cr, Mo, Ta, Ru, Co, Fe, B, Cu, Ti, V, or Pt. The underlayer can also be a MgO layer, or a Ru layer, or a Ta layer, or a TiCr layer, or a Pt layer, or a Pd layer, or a ruthenium oxide layer. The underlayer can also generally be a material deposited to have an amorphous structure.

The multilayer structure can be capped with a layer composed of any of, but not limited to, Ta, Ti, Ru, Mg, O, Cu, V, Hf, Fe, Pt, or ruthenium oxide.

The perpendicular anisotropy of the said multilayer stack in the perpendicular free layer can be achieved by depositing the perpendicular multilayer when the underlayer and substrate is held at temperature between 200° C. to 500° C. The perpendicular anisotropy can also be achieved by annealing the deposited multilayer stack at temperature of 200° C. to 500° C. A perpendicular magnetic field of larger than 1 kOe can be applied during the annealing process.

### Embodiment 4—MRAM MTJ Stack with Reference Layer having Multilayer Structure

In the fourth embodiment as illustrated in FIG. 6, the perpendicular free layer, perpendicular reference layer and perpendicular pinned layer all have a perpendicular magnetic anisotropy and a magnetization perpendicular to the film plane. The magnetizations of perpendicular reference layer and perpendicular pinned layer are opposite to each other. The junctions layer can be, but is not limited to, MgO, alumina, Cu or Cu nano-pillars within an oxide. When different electric current directions are applied through the stack, the perpendicular free layer magnetization can be switched into different orientation along the perpendicular direction due to the spin transfer torque from the perpendicular reference layer. The spacer layer may be a non-magnetic layer of, but is not limited to, Ru, Ta, Ti, MgO, Cu, Hf, ZnO, alumina, or ruthenium oxide. The spacer layer can be designed to produce an anti-ferromagnetic coupling between the perpendicular reference layer and perpendicular pinned layer, with composition of Ru, Cu or MgO.

In this embodiment the perpendicular reference layer is a multilayer stack formed by interlacing a soft magnetic layer and a perpendicular magnetic layer in N repeats, where N is a positive integer equal to or larger than 1. The soft magnetic layer is an amorphous layer when deposited. The soft magnetic layer is an alloy composed of any of, but is not limited to, Co, Fe, B, Ta, Ti, Cr, Ni, O, Mg, Cu, Hf, Pt, or Zr. For example, the soft magnetic layer can be composed of CoFeB. The soft magnetic layer can also be composed of CoFeBX, or CoFeX, or FeX, or NiFeX, or CoX, or CoNiX, where X can be any element of, Ta, Ti, Cr, Ni, O, Mg, Cu, Hf, or Sm. The soft magnetic layer can also be composed of at least one rare earth element of Tb, Gd, Nd, or Sm, and at least one element of Co, Fe, Ni, B, or Mn. For example, the soft magnetic layer can be composed of TbCoFe, or GdCoFe. The soft magnetic layer preferably has thickness between 0.2 nm to 2 nm.

The perpendicular magnetic layer can be composed of:
FePtY, where Y can be any of, but is not limited to , Cr, Cu, B, Ta, Ti, V, Si, C, Ru, O, or Zr.
CoPtY, where Y can be any of, but is not limited to , Cr, Cu, B, Ta, Ti, V, Si, C, Ru, O, or Zr.
CoCrZ, where Z can be any of, but is not limited to, Pt, Pd, Ta, Ti, Zr, Si, or Al.
CoCrZ, where Z can be any of, but is not limited to, Pt, Pd, Ta, Ti, Zr, Si, Al, in mixture within an oxide, where the oxide can be, silicon-oxide, MgO, alumina, zinc-oxide, or ruthenium oxide.
Co/Pd multilayer, or CoFe/Pd multilayer, or Co/Pt multilayer, or CoFe/Pt multilayer, or Fe/Pt multilayer, or Co/Ni multilayer, or CoFe/Ni multilayer. The notation Co/Pd, for example, is used to mean a pair of adjacent layers of Co and Pd.

The perpendicular magnetic layer preferably has thickness between 0.2 nm to 2 nm. The multilayer stack can end with a soft magnetic layer or a perpendicular magnetic layer on either top or bottom of the stack.

The perpendicular reference layer structure in this embodiment can have an interface layer (not shown) abutting the junction layer that can be composed of CoFe, or Fe, or CoFeB, where Fe atomic percentage is larger than or equal to 40%. The interface layer can also be composed of any one or multiple elements of, but not limited to, Cr, Mo, Ta, Ru, Co, Fe, B, Cu, Ti, V, or Pt. The interface layer can also be a MgO layer, or a Ru layer, or a Ta layer, or a TiCr layer, or a Pt layer, or a Pd layer. The interface layer can also generally be a material deposited to have an amorphous structure. The interface layer thickness is preferably between 0.2 nm to 2 nm.

The multilayer structure can be capped with a layer composed of any of, but not limited to, Ta, Ti, Ru, Mg, O, Cu, V, Hf, Fe, Pt, or ruthenium oxide.

The perpendicular anisotropy of the multilayer stack in the perpendicular reference layer can be achieved by depositing the perpendicular multilayer when the lower layers of the MTJ film stack is held at temperature between 200° C. to 400° C. The perpendicular anisotropy can also be achieved by annealing the deposited multilayer stack at temperature of 200° C. to 400° C. A perpendicular magnetic field of larger than 1 kOe can be applied during the annealing process.

### Embodiment 5—MRAM MTJ Stack with PL having Claimed Multilayer Structure

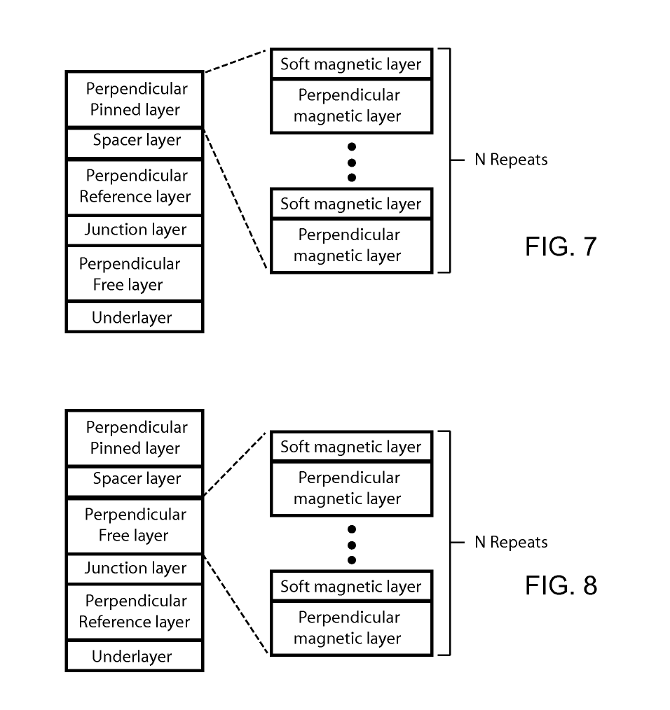

In the fifth embodiment as illustrated in FIG. 7, the perpendicular free layer, perpendicular reference layer and perpendicular pinned layer all have a perpendicular magnetic anisotropy and a magnetization perpendicular to the film plane. The magnetizations of perpendicular reference layer and perpendicular pinned layer are opposite to each other. The junction layer can be, but is not limited to, MgO, alumina, Cu or Cu nano-pillars within an oxide. When different electric current directions are applied through the stack, the perpendicular free layer magnetization may be switched into different orientation along the perpendicular direction due to the spin transfer torque from the perpendicular reference layer.

The spacer layer can be a non-magnetic layer of, but is not limited to, Ru, Ta, Ti, MgO, Cu, Hf, ZnO, alumina, or ruthenium oxide. The spacer layer can also be designed to produce an anti-ferromagnetic coupling between the perpendicular reference layer and perpendicular pinned layer, with composition of Ru, Cu or MgO.

In this embodiment the perpendicular pinned layer is a multilayer stack formed by interlacing a soft magnetic layer and a perpendicular magnetic layer in N repeats, where N is a positive integer equal to or larger than 1. The soft magnetic layer has an amorphous structure when deposited. The soft magnetic layer in this embodiment can be any of the following:
An alloy composed of any of, but not limited to, Co, Fe, B, Ta, Ti, Cr, Ni, O, Mg, Cu, Hf, Pt, or Zr.

CoFeB.
CoFeBX, or CoFeX, or FeX, or NiFeX, or CoX, or CoNiX, where X can be any element of, Ta, Ti, Cr, Ni, O, Mg, Cu, Hf, or Sm.
At least one rare earth element of Tb, Gd, Nd, Sm, and at least one element of Co, Fe, Ni, B, or Mn.
TbCoFe, or GdCoFe.
   The soft magnetic layer preferably has thickness between 0.2 nm to 2 nm.

The perpendicular magnetic layer in this embodiment may be composed of:
FePtY, where Y can be any of, but is not limited to , Cr, Cu, B, Ta, Ti, V, Si, C, Ru, O, or Zr.
CoPtY, where Y can be any of, but is not limited to , Cr, Cu, B, Ta, Ti, V, Si, C, Ru, O, or Zr.
CoCrZ, where Z can be any of, but is not limited to, Pt, Pd, Ta, Ti, Zr, Si, or Al.
CoCrZ, where Z can be any of, but is not limited to, Pt, Pd, Ta, Ti, Zr, Si, Al, in mixture within an oxide, where the oxide can be, silicon-oxide, MgO, alumina, zinc-oxide, or ruthenium oxide.
Co/Pd multilayer, or CoFe/Pd multilayer, or Co/Pt multilayer, or CoFe/Pt multilayer, or Fe/Pt multilayer, or Co/Ni multilayer, or CoFe/Ni multilayer.

The perpendicular layer preferably has thickness between 0.2 nm to 2 nm. The multilayer stack can be ended with a soft magnetic layer or a perpendicular magnetic layer on either top or bottom of the stack.

The perpendicular pinned layer structure can have an interface layer abutting the spacer layer that can be composed of CoFe, or Fe, or CoFeB, where Fe atomic percentage is larger than or equal to 40%. The interface layer can be composed of any one or multiple elements of, but is not limited to, Cr, Mo, Ta, Ru, Co, Fe, B, Cu, Ti, V, or Pt. The interface layer can also be a MgO layer, or a Ru layer, or a Ta layer, or a TiCr layer, or a Pt layer, or a Pd layer, or a ruthenium oxide layer. The interface layer can also generally be a material deposited to have an amorphous structure. The interface layer thickness is preferably between 0.2 nm to 2 nm.

The multilayer structure can be capped with a layer composed of any of, but is not limited to, Ta, Ti, Ru, Mg, O, Cu, V, Hf, Fe, Pt, or ruthenium oxide.

The perpendicular anisotropy of the multilayer stack in the perpendicular pinned layer can be achieved by depositing the perpendicular multilayer when the temperature of the lower layers of the MTJ film stack previously deposited is held at temperature between 200° C. to 400° C. The perpendicular anisotropy can also be achieved by annealing the deposited multilayer stack at temperature of 200° C. to 400° C. A perpendicular magnetic field of larger than 1 kOe can be applied during the annealing process.

### Embodiment 6—MRAM MTJ Stack with a Center Free Layer having Multilayer Structure

In the sixth embodiment as illustrated in FIG. 8, the free layer structure in the center of the MTJ layer stack and the multilayer structure of the invention is used for the free layer function. The perpendicular free layer, perpendicular reference layer and perpendicular pinned layer all have a perpendicular magnetic anisotropy and a magnetization perpendicular to the film plane. The magnetizations of perpendicular reference layer and perpendicular pinned layer are opposite to each other. The junction layer may be, but is not limited to, MgO, alumina, Cu and Cu nano-pillars within an oxide. When different electric current directions are applied through the stack, the perpendicular free layer magnetization can be switched into different orientation along the perpendicular direction due to the spin transfer torque from the perpendicular reference layer.

The spacer layer may be a non-magnetic layer of, but is not limited to, Ru, Ta, Ti, MgO, Cu, Hf, ZnO, alumina, or ruthenium oxide. The spacer layer can be designed to produce an anti-ferromagnetic coupling between the perpendicular reference layer and perpendicular pinned layer, with a composition of Ru, Cu or MgO.

The spacer layer can also be an oxide or a nitride or a carbide layer with a metal capping; wherein the oxide/nitride/carbide can contain any of Co, Fe, Ni, Mg, Al, Ta, Ti, Pt, Pd, Ru, Cu, Hf, Mn, Ir, Si, Zr, V, Nb, Cr, Mo and/or W; wherein the metal can be any of Co, Fe, Ni, Mg, Al, Ta, Ti, Pt, Pd, Ru, Cu, Hf, Mn, Ir, Zr, V, Nb, Cr, Mo and W.

The perpendicular free layer is a multilayer stack formed by interlacing a soft magnetic layer and a perpendicular magnetic layer in N repeats, where N is a positive integer equal to or larger than 1.

The soft magnetic layer is an amorphous layer when deposited and can be:
An alloy composed of any of, but not limited to, Co, Fe, B, Ta, Ti, Cr, Ni, O, Mg, Cu, Hf, Pt, Zr.
Composed of CoFeB.
Composed of CoFeBX, or CoFeX, or FeX, or NiFeX, or CoX, or CoNiX, where X can be any element of, Ta, Ti, Cr, Ni, O, Mg, Cu, Hf, or Sm.
Composed of at least one rare earth element of Tb, Gd, Nd, or Sm, and at least one element of Co, Fe, Ni, B, or Mn.
Composed of TbCoFe, or GdCoFe.
   The soft magnetic layer preferably has thickness between 0.2 nm to 2 nm.

The perpendicular magnetic layer can be composed of:
FePtY, where Y can be any of, but is not limited to , Cr, Cu, B, Ta, Ti, V, Si, C, Ru, O, Zr.
CoPtY, where Y can be any of, but is not limited to , Cr, Cu, B, Ta, Ti, V, Si, C, Ru, O, Zr.
CoCrZ, where Z can be any of, but is not limited to, Pt, Pd, Ta, Ti, Zr, Si, Al.
CoCrZ, where Z can be any of, but not limited to, Pt, Pd, Ta, Ti, Zr, Si, Al, in mixture within an oxide, where the oxide can be, silicon-oxide, MgO, alumina, zinc-oxide, ruthenium oxide.
Co/Pd multilayer, or CoFe/Pd multilayer, or Co/Pt multilayer, or CoFe/Pt multilayer, or Fe/Pt multilayer, or Co/Ni multilayer, or CoFe/Ni multilayer.

The perpendicular magnetic layer preferably has thickness between 0.2 nm to 2 nm.

The multilayer stack can be ended with soft magnetic layer or perpendicular magnetic layer on either top or bottom of the stack

The perpendicular free layer can have an interface layer abutting the junction layer, and may be composed of CoFe, or Fe, or CoFeB, where Fe atomic percentage is larger than or equal to 40%. The interface layer can be composed of:
Any one or multiple elements of, but is not limited to, Cr, Mo, Ta, Ru, Co, Fe, B, Cu, Ti, V, or Pt.
A MgO layer, or a Ru layer, or a Ta layer, or a TiCr layer, or a Pt layer, or a Pd layer.
A material deposited to have an amorphous structure.
   The interface layer thickness is preferably between 0.2 nm to 2 nm.

The multilayer structure may be capped with a layer composed of any of, but is not limited to, Ta, Ti, Ru, Mg, O, Cu, V, Hf, Fe, Pt, ruthenium oxide.

The perpendicular anisotropy of the multilayer stack in the perpendicular free layer may be achieved by depositing the perpendicular multilayer when the lower layers of the MTJ film stack is held at a temperature between 200° C. to 400° C. The perpendicular anisotropy can also be achieved by annealing the deposited multilayer stack at temperature of 200° C. to 400° C. A perpendicular magnetic field of larger than 1 kOe can be applied during the annealing process.

### Embodiment 7—MRAM MTJ Stack with Center Free Layer having Multilayer Structure

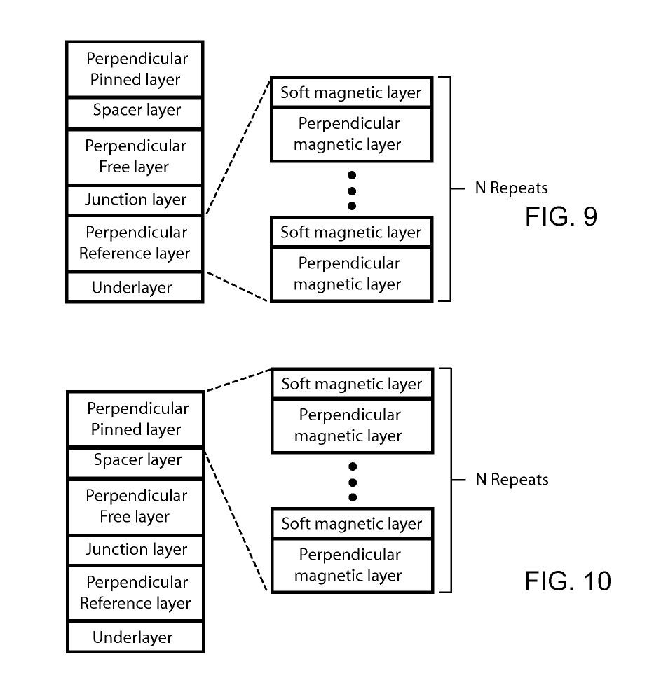

In the seventh embodiment as illustrated in FIG. 9, the perpendicular magnetic reference layer is a multilayer stack formed by interlacing soft magnetic layer and perpendicular magnetic layer in N repeats, where N is a positive integer equal to or larger than 1. The perpendicular free layer, perpendicular reference layer and perpendicular pinned layer all have a perpendicular magnetic anisotropy and a magnetization perpendicular to the film plane. The magnetizations of perpendicular reference layer and perpendicular pinned layer are opposite to each other. The junction layer can be, but is not limited to, MgO, alumina, Cu and Cu nano-pillars within an oxide.

When different direction electric current directions are applied through the stack, the perpendicular free layer magnetization can be switched into different orientation along the perpendicular direction due to the spin transfer torque from the perpendicular reference layer.

The spacer layer can be a non-magnetic layer of, but is not limited to, Ru, Ta, Ti, MgO, Cu, Hf, ZnO, or alumina. The spacer layer can also be designed to produce an anti-ferromagnetic coupling between the perpendicular reference layer and perpendicular pinned layer, with a composition of Ru, Cu or MgO. The spacer layer can also be an oxide or a nitride or a carbide layer with a metal capping; wherein the oxide/nitride/carbide can contain any of Co, Fe, Ni, Mg, Al, Ta, Ti, Pt, Pd, Ru, Cu, Hf, Mn, Ir, Si, Zr, V, Nb, Cr, Mo and W; wherein metal can be any of Co, Fe, Ni, Mg, Al, Ta, Ti, Pt, Pd, Ru, Cu, Hf, Mn, Ir, Zr, V, Nb, Cr, Mo and W.

The soft magnetic layer is an amorphous layer when deposited. The soft magnetic layer is an alloy composed of any of, but is not limited to, Co, Fe, B, Ta, Ti, Cr, Ni, O, Mg, Cu, Hf, Pt, Zr. For example, the soft magnetic layer can be composed of CoFeB. The soft magnetic layer can also be composed of CoFeBX, or CoFeX, or FeX, or NiFeX, or CoX, or CoNiX, where X can be any element of, Ta, Ti, Cr, Ni, O, Mg, Cu, Hf, or Sm. The soft magnetic layer can also be composed of at least one rare earth element of Tb, Gd, Nd, or Sm, and at least one element of Co, Fe, Ni, B, or Mn.The soft magnetic layer can also be composed of TbCoFe, or GdCoFe. The soft magnetic layer preferably has thickness between 0.2 nm to 2 nm.

The perpendicular magnetic layer preferably has thickness between 0.2 nm to 2 nm. The perpendicular magnetic layer can be composed of:
FePtY, where Y can be any of, but is not limited to , Cr, Cu, B, Ta, Ti, V, Si, C, Ru, O, Zr.
CoPtY, where Y can be any of, but is not limited to , Cr, Cu, B, Ta, Ti, V, Si, C, Ru, O, Zr.
CoCrZ, where Z can be any of, but is not limited to, Pt, Pd, Ta, Ti, Zr, Si, Al.
CoCrZ, where Z can be any of, but is not limited to, Pt, Pd, Ta, Ti, Zr, Si, Al, in mixture within an oxide, where the oxide can be, silicon-oxide, MgO, alumina, zinc-oxide, ruthenium oxide.
Co/Pd multilayer, or CoFe/Pd multilayer, or Co/Pt multilayer, or CoFe/Pt multilayer, or Fe/Pt multilayer, or Co/Ni multilayer, or CoFe/Ni multilayer.

The multilayer stack may be ended with soft magnetic layer or perpendicular magnetic layer on either top or bottom of the stack

The perpendicular reference layer may have an interface layer abutting the junction layer, and may be composed of CoFe, or Fe, or CoFeB, where Fe atomic percentage is larger than or equal to 40%.

The underlayer beneath the stack may be used to promote perpendicular anisotropy of the stack and can be composed of any one or multiple elements of, but is not limited to, Cr, Mo, Ta, Ru, Co, Fe, B, Cu, Ti, V, or Pt. The underlayer can also be a MgO layer, or a Ru layer, or a Ta layer, or a TiCr layer, or a Pt layer, or a Pd layer , a ruthenium oxide layer. The underlayer can also be a material deposited to have an amorphous structure.

The multilayer structure can be capped with layer composed of any of, but is not limited to, Ta, Ti, Ru, Mg, O, Cu, V, Hf, Fe, Pt , or ruthenium oxide.

The perpendicular anisotropy of the multilayer stack in the perpendicular reference layer may be achieved by depositing the perpendicular multilayer when the underlayer and substrate is held at temperature between 200° C. to 500° C. The perpendicular anisotropy can also be achieved by annealing the deposited multilayer stack at temperature of 200° C. to 500° C. A perpendicular magnetic field of larger than 1 kOe can be applied during the annealing process.

### Embodiment 8—MRAM MTJ Stack with a Center Free Layer having the Multilayer Structure

In the eight embodiment as illustrated in FIG. 10, the perpendicular pinned layer is a multilayer stack formed by interlacing a soft magnetic layer and a perpendicular magnetic layer in N repeats, where N is a positive integer equal to or larger than 1. The perpendicular free layer, perpendicular reference layer and perpendicular pinned layer all have a perpendicular magnetic anisotropy and a magnetization perpendicular to the film plane. The magnetizations of the perpendicular reference layer and the perpendicular pinned layer are opposite to each other. The junction layer can be, but is not limited to, MgO, alumina, Cu and Cu nano-pillars within an oxide. When different direction electric current directions are applied through the stack, the perpendicular free layer magnetization can be switched into different orientations along the perpendicular direction due to the spin transfer torque from the perpendicular reference layer.

The spacer layer can be a non-magnetic layer of, but is not limited to, Ru, Ta, Ti, MgO, Cu, Hf, ZnO, or alumina. The spacer layer can also be designed to produce an anti-ferromagnetic coupling between the perpendicular reference layer and perpendicular pinned layer, with a composition of Ru, Cu or MgO. The spacer layer can also be an oxide or a nitride or a carbide layer with a metal capping; wherein the oxide/nitride/carbide can contain any of Co, Fe, Ni, Mg, Al, Ta, Ti, Pt, Pd, Ru, Cu, Hf, Mn, Ir, Si, Zr, V, Nb, Cr, Mo and W; wherein metal can be any of Co, Fe, Ni, Mg, Al, Ta, Ti, Pt, Pd, Ru, Cu, Hf, Mn, Ir, Zr, V, Nb, Cr, Mo and W.

The soft magnetic layer is an amorphous layer when deposited and preferably has thickness between 0.2 nm to 2 nm. The soft magnetic layer can be:
An alloy composed of any of, but is not limited to, Co, Fe, B, Ta, Ti, Cr, Ni, O, Mg, Cu, Hf, Pt, and Zr.
Composed of CoFeB.
Composed of CoFeBX, or CoFeX, or FeX, or NiFeX, or CoX, or CoNiX, where X can be any element of, Ta, Ti, Cr, Ni, O, Mg, Cu, Hf, or Sm.
Composed of at least one rare earth element of Tb, Gd, Nd, or Sm, and at least one element of Co, Fe, Ni, B, or Mn.
Composed of TbCoFe, or GdCoFe.

The perpendicular magnetic layer preferably has a thickness between 0.2 nm to 2 nm and can be composed of:
FePtY, where Y can be any of, but is not limited to , Cr, Cu, B, Ta, Ti, V, Si, C, Ru, O, and/or Zr.
CoPtY, where Y can be any of, but is not limited to , Cr, Cu, B, Ta, Ti, V, Si, C, Ru, O, and/or Zr.
CoCrZ, where Z can be any of, but is not limited to, Pt, Pd, Ta, Ti, Zr, Si, and/or Al.
CoCrZ, where Z can be any of, but is not limited to, Pt, Pd, Ta, Ti, Zr, Si, Al, in mixture within an oxide, where the oxide can be, silicon-oxide, MgO, alumina, zinc-oxide, or ruthenium oxide.
Co/Pd multilayer, or CoFe/Pd multilayer, or Co/Pt multilayer, or CoFe/Pt multilayer, or Fe/Pt multilayer, or Co/Ni multilayer, or CoFe/Ni multilayer.

The multilayer stack can be ended with a soft magnetic layer or a perpendicular magnetic layer on either top or bottom of the stack.

The perpendicular pinned layer can have an interface layer abutting the spacer layer, and may be composed of CoFe, or Fe, or CoFeB, where Fe atomic percentage is larger than or equal to 40%. The interface layer can also be composed of any one or multiple elements of, but is not limited to, Cr, Mo, Ta, Ru, Co, Fe, B, Cu, Ti, V, and/or Pt. The interface layer can also be a MgO layer, or a Ru layer, or a Ta layer, or a TiCr layer, or a Pt layer, or a Pd layer , or a ruthenium oxide layer. The interface layer can also generally be a material deposited with an amorphous structure. The interface layer thickness is preferably between 0.2 nm to 2 nm.

The multilayer structure can be capped with layer composed of any of, but is not limited to, Ta, Ti, Ru, Mg, O, Cu, V, Hf, Fe, Pt , and/or ruthenium oxide.

The perpendicular anisotropy of the multilayer stack in the perpendicular pinned layer can be achieved by depositing the perpendicular multilayer when the temperature of the lower layers of the MTJ film stack is held at temperature between 200° C. to 400° C. The perpendicular anisotropy can also be achieved by annealing the deposited multilayer stack at temperature of 200° C. to 400° C. A perpendicular magnetic field of larger than 1 kOe can be applied during the annealing process.

Although the present invention has been described in terms of specific embodiments, it is anticipated that alterations and modifications thereof will no doubt become apparent to those skilled in the art. It is therefore intended that the following claims be interpreted as covering all such alterations and modifications as fall within the true spirit and scope of the invention.

1. A thin film structure comprising:
an underlayer;
a multilayer structure deposited on the underlayer including at least two pairs of layers including a FePt based magnetic layer having perpendicular anisotropy and a soft magnetic layer adjacent to the FePt based magnetic layer.

2. The thin film structure of claim 1 wherein the multilayer structure includes more than two pairs of layers with each pair including a FePt based magnetic layer having perpendicular anisotropy and a soft magnetic layer adjacent to the FePt based magnetic layer.

3. The thin film structure of claim 1 wherein the FePt based magnetic layer is an alloy composed of Fe and Pt and at least one element from the group consisting of Cu, B, Ta, Ti, V, Cr, Si, C, and Ru.

4. The thin film structure of claim 1 wherein the FePt based magnetic layer is FePtCuB.

5. The thin film structure of claim 1 wherein the multilayer structure serves as a free layer, a pinned layer or a reference layer in an MTJ.

6. The thin film structure of claim 1 wherein the soft magnetic layer is an alloy composed of elements from the group consisting of Co, Fe, B, Ta, Ti, Cr, Ni, O, Mg, Cu, Hf, and Pt.

7. The thin film structure of claim 1 wherein the soft magnetic layer includes CoFe, CoFeB, or CoFeBX, where X can be any element from the group consisting of Ta, Ti, Cr, Ni, O, Mg, Cu, and Hf.

8. The thin film structure of claim 1 wherein the soft magnetic layer includes a plurality of layers of CoFe or CoFeB.

9. The thin film structure of claim 1 wherein the soft magnetic layer is includes Co, Fe, or B, and any element of the group consisting of Ta, Ti, Cr, Ni, O, Mg, Cu, and Hf.

10. The thin film structure of claim 1 wherein the underlayer is composed of Cr, Mo, Ta, Ru, Co, Fe, B, Cu, Ti, V, or Pt or alloys thereof .

11. The thin film structure of claim 1 wherein the underlayer has an amorphous structure.

12. The thin film structure of claim 1 wherein the underlayer includes a plurality of layers from bottom to top of a Ta layer, a CoFeB layer, and a CrMo layer.

13. The thin film structure of claim 1 wherein the underlayer is MgO, Ru, Ta, CrMo, Pt, or ruthenium oxide.

14. The thin film structure of claim 1 wherein the underlayer is composed of at least Co, Fe, B and at least one element from the group consisting of Ta, Ti, Cr, Ni, O, Mg, Cu, and Hf.

15. A thin film magnetic device comprising:
a multilayer structure including at least two pairs of layers that include a magnetic layer having perpendicular anisotropy and a soft magnetic layer adjacent to the magnetic layer.

16. The thin film magnetic device of claim 15 wherein the multilayer structure includes more than two pairs of layers with each pair including magnetic layer having perpendicular anisotropy and a soft magnetic layer adjacent to the magnetic layer.

17. The thin film magnetic device of claim 15 wherein the soft magnetic layer has an amorphous structure when deposited.

18. The thin film magnetic device of claim 15 wherein the soft magnetic layer is an alloy composed of elements from the group consisting of Co, Fe, B, Ta, Ti, Cr, Ni, O, Mg, Cu, Hf, Pt, and Zr.

19. The thin film magnetic device of claim 15 wherein the soft magnetic layer is composed of CoFeBX, or CoFeX, or FeX, or NiFeX, or CoX, or CoNiX, where X is any element from the group Ta, Ti, Cr, Ni, O, Mg, Cu, Hf, and Sm.

20. The thin film magnetic device of claim 15 wherein the soft magnetic layer is composed of at least one rare earth element of Tb, Gd, Nd, Sm, and at least one element from the group Co, Fe, Ni, B, and Mn.

21. The thin film magnetic device of claim 15 wherein the soft magnetic layer is composed of TbCoFe or GdCoFe.

22. The thin film magnetic device of claim 15 wherein the magnetic layer is composed of FePtY, where Y is Cr, Cu, B, Ta, Ti, V, Si, C, Ru, O, or Zr.

23. The thin film magnetic device of claim 15 wherein the magnetic layer is composed of CoPtY, where Y is Cr, Cu, B, Ta, Ti, V, Si, C, Ru, O, or Zr.

24. The thin film magnetic device of claim 15 wherein the magnetic layer is composed of CoCrZ, where Z is Pt, Pd, Ta, Ti, Zr, Si, or Al. [Misnumbered Second Claim Number] 24. (canceled)

25. The thin film magnetic device of claim 15 wherein the magnetic layer is composed of multiple adjacent layers of Co and Pd; multiple adjacent layers of CoFe and Pd; multiple adjacent layers of Co and Pt;, multiple adjacent layers of CoFe and Pt; multiple adjacent layers of Fe and Pt; multiple adjacent layers of Co and Ni; or multiple adjacent layers of CoFe and Ni .

26. The thin film magnetic device of claim 15 further comprising an underlayer beneath the multilayer structure composed of any one or alloys of Cr, Mo, Ta, Ru, Co, Fe, B, Cu, Ti, V, or Pt.

27. The thin film magnetic device of claim 15 further comprising an amorphous underlayer beneath the multilayer structure.

28. The thin film magnetic device of claim 15 the multilayer structure further comprising a capping layer composed of Ta, Ti, Ru, Mg, O, Cu, V, Hf, Fe, Pt, or ruthenium oxide.

29. The thin film magnetic device of claim 15 wherein the device is an MRAM MTJ cell and the multilayer structure is a free layer.

30. The thin film magnetic device of claim 15 wherein the device is an MRAM MTJ cell and the multilayer structure is a reference layer.

31. The thin film magnetic device of claim 15 wherein the device is an MRAM MTJ cell and the multilayer structure is a pinned layer.

32. The thin film magnetic device of claim 15 wherein the magnetic layer is composed of CoCrZ, where Z is Pt, Pd, Ta, Ti, Zr, Si, or Al, in mixture within an oxide, where the oxide is silicon-oxide, MgO, alumina, zinc-oxide, or ruthenium oxide.
